(19) United States
(12) Patent Application Publication
(10) Pub. No.: US 2019/0006621 A1
(43) Pub. Date: Jan. 3, 2019

(54) DISPLAY DEVICE

(71) Applicant: Japan Display Inc., Minato-ku (JP)

(72) Inventor: Kengo KATO, Minato-ku (JP)

(73) Assignee: Japan Display Inc., Minato-ku (JP)

(21) Appl. No.: 16/008,155

(22) Filed: Jun. 14, 2018

(30) Foreign Application Priority Data
Jun. 30, 2017 (JP) 2017-128824

(51) Int. Cl. H01L 51/52

(52) U.S. Cl. CPC H01L 51/5253; H01L 51/5275

(57) ABSTRACT

A display device may include a lower electrode; an electroluminescence layer on the lower electrode; an upper electrode on the electroluminescence layer; a cap layer on the upper electrode for improving light extraction efficiency; an absorbent layer on the cap layer, the absorbent layer extending from above and laterally next to the cap layer; and a sealing film on the absorbent layer.

### CROSS-REFERENCE TO RELATED APPLICATION

The present application claims priority from Japanese application JP2017-128824 filed on Jun. 30, 2017, the content of which is hereby incorporated by reference into this application.

### BACKGROUND OF THE INVENTION

### 1. Field of the Invention

This relates to display devices.

### 2. Description of the Related Art

Recently, displays equipped with illuminants such as organic electroluminescence have been developing (JP H09-304796A and JP 2000-030857A). Organic electroluminescence elements, which are vulnerable to moisture, are configured to be covered with a sealing film (JP 2000-030857A). To improve barrier properties, a kind of sealing film is known to have a structure where an organic layer is interposed between a pair of inorganic films.

A cap layer is technically used for gradually changing refractive indexes to improve light extraction efficiency. With a defect in the sealing film, water enters there and diffuses into the cap layer, changing the refractive index in the material of the cap layer. Then, the light extraction efficiency cannot improve.

This is to aim at curbing deterioration of the cap layer.

### SUMMARY OF THE INVENTION

A display device may include a lower electrode; an electroluminescence layer on the lower electrode; an upper electrode on the electroluminescence layer; a cap layer on the upper electrode for improving light extraction efficiency; an absorbent layer on the cap layer, the absorbent layer extending from above and laterally next to the cap layer; and a sealing film on the absorbent layer.

The cap layer is prevented from deterioration by the absorbent layer provided not only above it but also laterally next to it.

### BRIEF DESCRIPTION OF THE DRAWINGS

FIG. 1 is a plan view of a display device in accordance with an embodiment.

FIG. 2 is a circuit diagram of the display device in FIG. 1.

FIG. 3 is an enlarged view of a portion of line cross section of the display device in FIG. 1.

FIG. 4 is an enlarged view of a portion of IV-IV line cross section of the display device in FIG. 1.

### DETAILED DESCRIPTION OF THE INVENTION

Hereinafter, some embodiments will be described with reference to the drawings. Here, the invention can be embodied according to various aspects within the scope of the invention without departing from the gist of the invention and is not construed as being limited to the content described in the embodiments exemplified below.

The drawings are further schematically illustrated in widths, thickness, shapes, and the like of units than actual forms to further clarify description in some cases but are merely examples and do not limit interpretation of the invention. In the present specification and the drawings, the same reference numerals are given to elements having the same functions described in the previously described drawings and the repeated description will be omitted.

Further, in the detailed description, “on” or “under” in definition of positional relations of certain constituents and other constituents includes not only a case in which a constituent is located just on or just under a certain constituent but also a case in which another constituent is interposed between constituents unless otherwise mentioned.

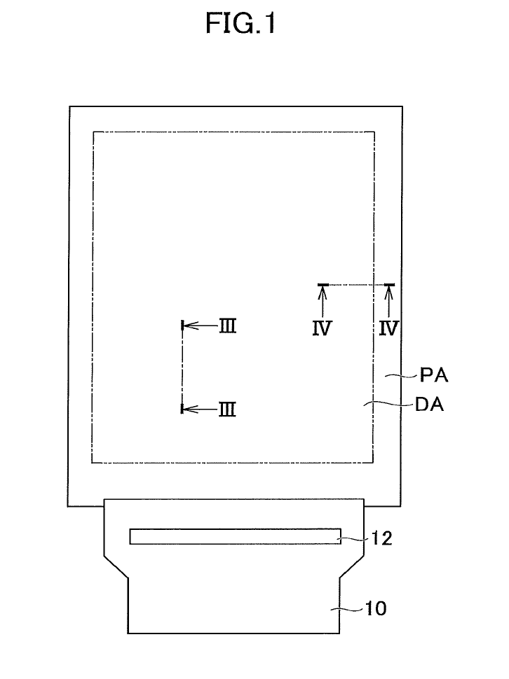

FIG. 1 is a plan view of a display device in accordance with an embodiment. The display device is an organic electroluminescence display device. The display device is configured to display a full-color image in full-color pixels, each of which consists of combination of unit pixels (subpixels) of colors such as red, green, and blue. The display device includes a display area DA and a peripheral area PA around the display area DA. A flexible printed circuit board 10 is connected to the peripheral area PA. On the flexible printed circuit board 10 is mounted an integrated circuit chip 12 for driving elements to display the image.

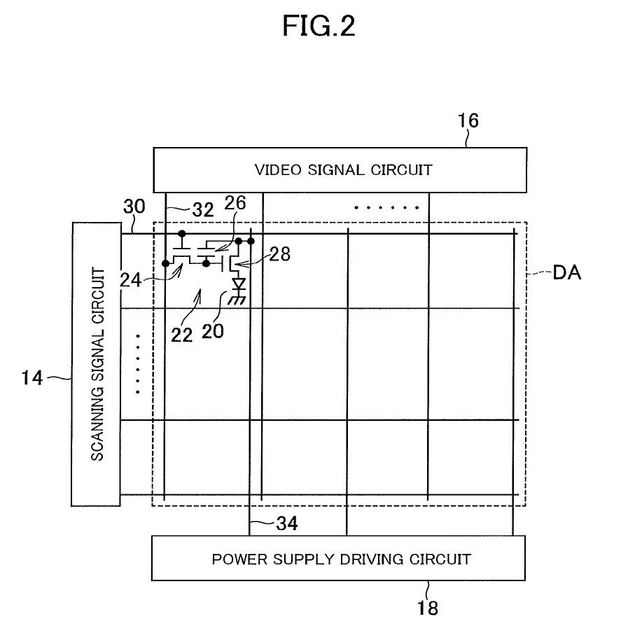

FIG. 2 is a circuit diagram of the display device in FIG. 1. The display device is equipped with a scanning signal circuit 14, a video signal circuit 16, and a power supply driving circuit 18. In the display area DA, display elements 20 and pixel circuits 22 are provided in a matrix, for respective pixels. The pixel circuit 22 includes a thin film transistor 24, a capacitor 26, and a thin film transistor 28. The scanning signal circuit 14, the video signal circuit 16, and the power supply driving circuit 18 are to drive the pixel circuit 22 and control light emission of the display element 20.

The scanning signal circuit 14 is connected to a scanning signal line 30 provided for each of horizontal rows (pixel rows) of pixels and is configured for outputting a scanning signal to the selected one of the scanning signal lines 30. The scanning signal controls the thin film transistor 24.

The video signal circuit 16 is connected to a video signal line 32 provided for each of vertical columns (pixel columns) of pixels and is configured for outputting a video signal. The scanning signal circuit selects one of the scanning signal lines 30 to turn on the corresponding thin film transistor 24 and writes on the capacitor 26 the video signal output to the video signal line 32.

The thin film transistor 28 is controlled in accordance with the voltage written on the capacitor 26. The thin film transistor 28 controls a current to be supplied to the display element 20 from a driving power line 34 provided for each pixel column and connected to the power supply driving circuit 18. The display element 20 has its brightness controlled by the current control. The display element 20 is grounded on a side opposite to the thin film transistor 28.

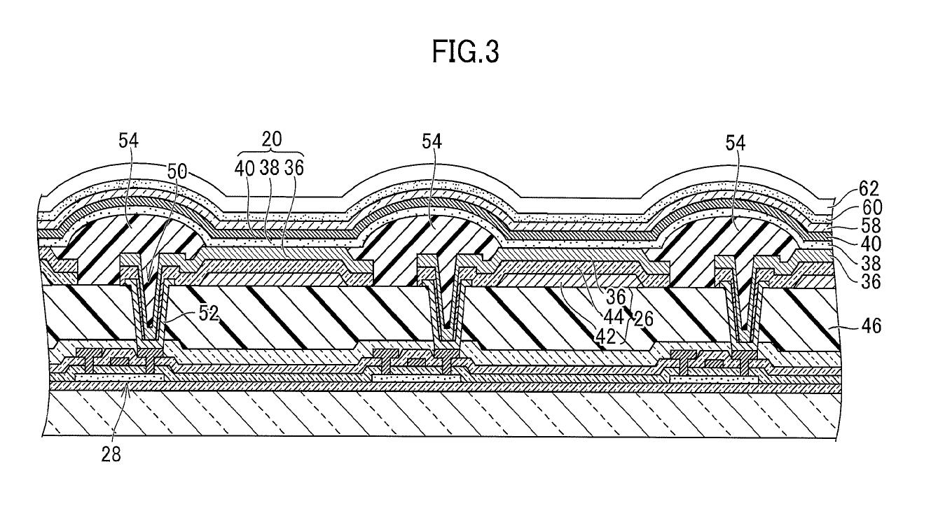

FIG. 3 is an enlarged view of a portion of line cross section of the display device in FIG. 1. The display element 20 includes a lower electrode 36 (pixel electrode or anode), an organic electroluminescence layer 38, and an upper electrode 40 (common electrode or cathode).

Under the lower electrode 36 are a capacitance electrode 42 and a capacitive insulation layer 44, which constitute a capacitor 26. The capacitive insulation layer 44 is made from inorganic insulation material such as silicon nitride (SiNx). Under the display element 20 and the capacitor 26 is a planarization film 46 made from an organic insulation film such as an acrylic resin or a polyimide resin.

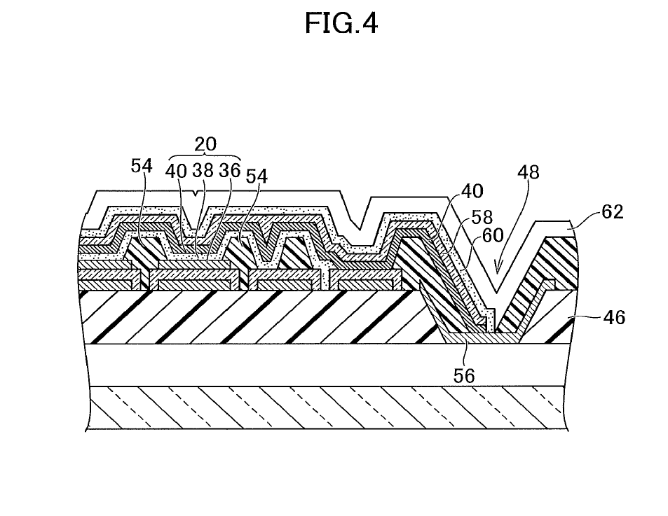

FIG. 4 is an enlarged view of a portion of IV-IV line cross section of the display device in FIG. 1. The planarization film 46 is disunited in the peripheral area PA. Specifically, the planarization film 46 has a continuous portion from the display area DA to the peripheral area PA, the continuous portion surrounded by another portion in the peripheral area PA. Disuniting the planarization film 46 as such forms a trench 48. The trench 48 exposes an inorganic insulation film or a metal layer but excludes an organic material such as the planarization film 46. Or, the trench 48 disunites the organic material and prevents moisture from permeating the organic material. This prevents moisture from entering into the organic electroluminescence layer 38.

The lower electrode 36, which is made from metal with light reflectivity such as aluminum, extends to a bottom of the contact hole 50 in FIG. 3 and is connected to a conducting layer 52 made from a transparent conductive film. The lower electrode 36 has continuity with one of the source electrode and the drain electrode of the thin film transistor 28 under the planarization film 46, through the conducting layer 52. To separate the pixels, a bank layer 54 made from an organic insulation film (resin) is provided. The bank layer 54 is configured to be on a periphery of the lower electrode 36.

The organic electroluminescence layer 38, which is between the upper electrode 40 and the lower electrode 36, includes a hole transport layer, a hole transport layer, a light emitting layer, an electron transport layer, and an electron injection layer. Some layers except for the light emitting layer continuously overlap with a plurality of lower electrode 36, whereas the light emitting layer is individually disposed for each lower electrode 36. The light emitting layer generates light due to recombination of holes injected from the lower electrode 36 and electrons injected from the upper electrode 40.

The upper electrode 40 is formed from a transparent conductive film such as indium tin oxide (ITO), in a widely spread shape to be a common one layer for the plurality of pixels in the display area DA. As shown in FIG. 4, the upper electrode 40 is connected to a cathode contact 56 in the peripheral area PA. The cathode contact 56 is illustrated in the trench 48.

The display device includes a cap layer 58. The cap layer 58 is on the upper electrode 40 entirely in the display area DA to improve light extraction efficiency. The cap layer 58 further extends to the peripheral area PA. The cap layer 58 has its thickness and its refractive index selected in accordance with emission intensity and emission wavelength of light from the organic electroluminescence layer 38. The cap layer serves as a protective layer for the organic electroluminescence layer 38 including the upper electrode 40. The cap layer 58 is formed from publicly known inorganic material. The material of the cap layer 58 preferably has a refractive index of 1.0 or more. The best method of forming the cap layer 58 is selected in accordance with the material thereof. The cap layer 58 generally has its thickness of 5 nm to 100 nm preferably for effective emission of light although it is not limited.

The display device has an absorbent layer 60, which may include calcium or calcium oxide. The absorbent layer 60 is on the cap layer 58. The absorbent layer 60 spreads all over the display area DA and further extends to the peripheral area PA. The absorbent layer 60 continuously extends from above and laterally next to the cap layer 58. As shown in FIG. 4, the cap layer 58 is illustrated to have its tip surface of the periphery covered with and in contact with the absorbent layer 60, in the trench 48. The periphery (e.g. whole periphery) of the absorbent layer 60 is at a lower position than the cap layer 58. The absorbent layer 60 entirely surrounds the cap layer 58. Specifically, the absorbent layer 60 extends beyond a whole periphery of the cap layer 58 and covers a whole surface of the cap layer 58 except for its bottom surface. In accordance with the embodiment, the cap layer 58 is prevented from deterioration due to the absorbent layer 60 not only above it but also laterally next to it.

The absorbent layer 60 further covers the upper electrode 40 at its periphery from its side and is in contact with the upper electrode 40 at its periphery. The absorbent layer 60 entirely surrounds the upper electrode 40 and is also in contact with a layer (cathode contact 56) under the periphery of the upper electrode 40.

The absorbent layer 60 extends from above and laterally next to the organic electroluminescence layer 38. As shown in FIG. 4, the absorbent layer 60 is illustrated to have its periphery at a position lower than a periphery of the organic electroluminescence layer 38. The absorbent layer 60 entirely surrounds the organic electroluminescence layer 38.

The display device has a sealing film 62. The display element 20 is covered with the sealing film 62 for its protection. The sealing film 62 has a structure where an organic film is interposed between inorganic layers over and under it; the inorganic layer may be made from silicon nitride or silicon oxide. The sealing film 62 is on the absorbent layer 60. The sealing film extends from above and laterally next to each of the absorbent layer 60, the cap layer 58, and the organic electroluminescence layer 38. The sealing film 62 entirely surrounds each of the absorbent layer 60, the cap layer 58, and the organic electroluminescence layer 38.

The display device is not limited to the organic electroluminescence display device but may be a display device with a light-emitting element disposed in each pixel, such as a quantum-dot light-emitting diode (QLED).

While there have been described what are at present considered to be certain embodiments, it will be understood that various modifications may be made thereto, and it is intended that the appended claims cover all such modifications as fall within the true spirit and scope of the invention.

What is claimed is:

1. A display device comprising:
a lower electrode;
an electroluminescence layer on the lower electrode;
an upper electrode on the electroluminescence layer;
a cap layer on the upper electrode for improving light extraction efficiency;
an absorbent layer on the cap layer, the absorbent layer extending from above and laterally next to the cap layer; and
a sealing film on the absorbent layer.

2. The display device according to claim 1, wherein the absorbent layer entirely surrounds the cap layer.

3. The display device according to claim 1, wherein the absorbent layer extends from above and laterally next to the electroluminescence layer.

4. The display device according to claim 3, wherein the absorbent layer entirely surrounds the electroluminescence layer.

5. The display device according to claim 1, wherein the sealing film extends from above and laterally next to each of the absorbent layer, the cap layer, and the electroluminescence layer.

6. The display device according to claim 5, wherein the sealing film entirely surrounds each of the absorbent layer, the cap layer, and the electroluminescence layer.
